(19) United States
(12) Patent Application Publication
(10) Pub. No.: US 2011/0100461 A1
(43) Pub. Date: May 5, 2011

(54) ELECTROLYTE COMPOSITION AND DYE-SENSITIZED SOLAR CELL HAVING THE SAME

(75) Inventors: Kuan-Wei LEE, Taoyuan (TW); Hsin-Yi Chen, Taoyuan (TW)

(73) Assignee: EVERLIGHT USA, INC., Pineville, NC (US)

(21) Appl. No.: 12/651,574

(22) Filed: Jan. 4, 2010

(30) Foreign Application Priority Data
Nov. 5, 2009 (TW) 098137536

(51) Int. Cl. H01L 31/00

(52) U.S. Cl. 136/261; 252/62.2; 136/263

(57) ABSTRACT

The present invention provides an electrolyte composition for a dye-sensitized solar cell, and the electrolyte composition includes 2 to 25 wt % of an organic amine hydroiodide; 2 to 25 wt % of an imidazolium salt; 0.5 to 5 wt % of iodine; 1 to 5 wt % of guanidine thiocyanate; 2 to 15 wt % of a benzimidazole derivative, a pyridine derivative or a combination thereof; and 50 to 92.5 wt % of a solvent. The present invention further provides a dye-sensitized solar cell, including a photoanode, a cathode having a surface in contact with the photoanode; and an electrolyte layer formed on the surface of the cathode. The dye-sensitized solar cell having the electrolyte composition of the present invention has outstanding photoelectric conversion efficiency and stability, and also the ingredients of the electrolyte composition have great compatibility to one another.

### BACKGROUND OF THE INVENTION

1. Field of the Invention

The present invention relates to an electrolyte composition, and more particularly, to an electrolyte composition for a dye-sensitized solar cell.

2. Description of Related Art

Energy crisis and environmental pollutions are global urgent issues. It is an importation solution to relief the energy crisis and to eliminate further environmental pollutions that a solar cell is used for transferring solar energy into electrical energy. In particular, it is a trend to develop a dye-sensitized solar cell, which is flexible and transparent to be applicable to a building, can be produced as a cell with a large are, and has low fabrication cost.

Gratzel et al. have publications (for example, O'Regan, B.; Grätzel, M. Nature 1991, 353, 737) about dye-sensitized solar cells, and demonstrate that dye-sensitized solar cells are practically applicable. Generally, a dye-sensitized solar cell includes an anode, a cathode, nano titanium dioxide, a dye and an electrolyte, wherein the electrolyte is critical to the efficiency of the cell. In a dye-sensitized solar cell, an ideal electrolyte should be nonvolatile, non-leaking, easy to be packaged, and unharmful to dyes and other compositions.

It is known that the liquid electrolyte has high efficiency of converting light into electricity. However, the liquid electrolyte has the disadvantages such as being volatile, leaking and hard to be packed. In order to overcome the above defects, many methods are developed such as providing an ionic liquid (N. Papageorgiou et al., J. Electrochem. Soc, 1996, 143, 3099) and a gel electrolyte including a polymer and an organic molten salt (U.S. Pat. No. 6,245,847).

The electrolyte in a dye-sensitized solar cell is critical to the efficiency of the cell. Therefore, it is an urgent issue in the industry to develop electrolytes for improving efficiency of a dye-sensitized solar cell.

### SUMMARY OF THE INVENTION

The present invention provides an electrolyte composition for a dye-sensitized solar cell, and the electrolyte composition includes 2 to 25 wt % of an organic amine hydroiodide; 2 to 25 wt % of an imidazolium salt; 0.5 to 5 wt % of iodine; 1 to 5 wt % of guanidine thiocyanate; 2 to 15 wt % of a benzimidazole derivative, a pyridine derivative or a combination thereof; and 50 to 92.5 wt % of a solvent.

Preferably, the electrolyte composition includes 5 to 20 wt % of an organic amine hydroiodide; 2 to 20 wt % of an imidazolium salt; 0.5 to 3 wt % of iodine; 1 to 3 wt % of guanidine thiocyanate; 5 to 10 wt % of a benzimidazole derivative, a pyridine derivative or a combination thereof; and 60 to 86.5 wt % of a solvent. More preferably, the electrolyte composition includes 15.1 wt % of an organic amine hydroiodide; 2.3 wt % of an imidazolium salt; 1.3 wt % of iodine; 1.2 wt % of guanidine thiocyanate; 8.7 wt % of a benzimidazole derivative, a pyridine derivative or a combination thereof; and 71.4 wt % of a solvent.

In one embodiment, the organic amine hydroiodide is one selected from the group consisting of triethylamine hydroiodide, tripropylamine hydroiodide, tributylamine hydroiodide, tripentylamine hydroiodide, trihexylamine hydroiodide and a combination thereof. Specifically, the organic amine hydroiodide of the electrolyte composition may include two or more of the previously identified organic amine hydroiodide. In addition, the organic amine hydroiodide is preferably one selected from the group consisting of triethylamine hydroiodide, tripropylamine hydroiodide, tributylamine hydroiodide, and a combination thereof. More preferably, the organic amine hydroiodide is triethylamine hydroiodide.

The imidazolium salt of the electrolyte composition is one selected from the group consisting of 1-methyl-3-propylimidazolium iodide (PMII), 1,3-dimethylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1-methyl-3-heptylimidazolium iodide, 1-methyl-3-octylimidazolium iodide, 1,3-diethylimidazolium iodide, 1-ethyl-3-propylimidazolium iodide, 1-ethyl-3-butylimidazolium iodide, 1,3-propylimidazolium iodide, 1-propyl-3-butylimidazolium iodide and a combination thereof. Preferably, the imidazolium salt of the electrolyte composition is one selected from the group consisting of 1-methyl-3-propylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1,3-diethylimidazolium iodide, 1-ethyl-3-propylimidazolium iodide, 1-ethyl-3-butylimidazolium iodide, 1,3-dipropylimidazolium iodide, 1-propyl-3-butylimidazolium iodide and a combination thereof. N,N-substituted imidazolium salt is preferably 1-methyl-3-propylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1,3-diethylimidazolium iodide, 1-ethyl-3-propylimidazolium iodide, 1-ethyl-3-butylimidazolium iodide, and a combination thereof. More preferably, the imidazolium salt is 1-methyl-3-propylimidazolium iodide, 1-methyl-3-ethylimidazolium iodide, 1-methyl-3-butylimidazolium iodide, 1-methyl-3-pentyl-imidazolium iodide, 1,3-diethylimidazolium iodide, 1-ethyl-3-propylimidazolium iodide, and a combination thereof.

In one embodiment of the present invention, the benzimidazole derivative, the pyridine derivative or the combination thereof may be one selected from the group consisting of N-methylbenzimidazole (NMBI), N-butylbenzimidazole (NBB), 4-tert-Butylpyridine (4-TBP) and a combination thereof.

In one embodiment of the present invention, the solvent is one selected from the group consisting of acetonitrile, 3-methoxyl-propionitrile (3-MPN), N-methyl-2-pyrrolidone (NMP), gamma-butyrolactone (GBL), propylene carbonate (PC), ethylene carbonate (EC) and a combination thereof.

In another aspect, the present invention provides a dye-sensitized solar cell having the electrolyte composition of the present invention. The dye-sensitized solar cell of the present invention includes a photoanode having a dye compound; a cathode; and an electrolyte layer having the electrolyte composition and formed between the photoanode and the cathode. Specifically, the electrolyte layer is formed on a surface of the cathode, wherein the surface of the cathode in contact with the photoanode.

In the dye-sensitized solar cell of the present invention, the photoanode includes substrate, a porous semiconductor film, an electrically conductive film formed between the substrate and the porous semiconductor film, and a dye compound disposed on the electrically conductive film and filled in the porous semiconductor film. Practically, a transparent substrate and a transparent electrically conductive film are used, and the material of the transparent substrate is not limited. Preferably, the material of the transparent substrate has good waterproof or gas-proof, solvent-tolerance and climate-tolerance. The transparent substrate may be, but not limited to, a substrate made of an inorganic transparent material such as quartz or glass, or a substrate made of a transparent plastic material such as polyethylene terephthalate (PET), polyethylene naphthalate (PEN), polycarbonate (PC), polyethylene (PE), polypropylene (PP) and polyimide (PI). In addition the thickness of the transparent substrate is not limited, but depends upon transparent index and the requirement of the dye-sensitized solar cell. More preferably, the transparent substrate is a glass.

In the dye-sensitized solar cell of the present invention, the material of the electrically conductive film may be Indium tin oxide (ITO), fluorinated tin oxide (FTO), ZnO—Ga₂O₃, ZnO—Al₂O₃ or tin-based oxide.

In the dye-sensitized solar cell of the present invention, the porous semiconductor film may be made of semiconductor particles. The semiconductor particle may be one selected from the group consisting of silicon, titanium dioxide, tin dioxide, zinc oxide, tungsten trioxide, niobium pentoxide, strontium titanium oxide and a combination thereof. The semiconductor particle is preferably titanium dioxide. Generally, the average diameter of the semiconductor particle is in a range from 5 to 500 nanometers, and preferably in a range from 10 to 50 nanometers. The thickness of the porous semiconductor film is in a range from 5 to 25 micrometers.

In the dye-sensitized solar cell of the present invention, the material of the cathode is not limited. Further, the cathode may be an insulated substrate coated with a conductive layer toward the photoanode. Generally, an electrochemically stable material may be a cathode, and is not limited to platinum, gold, carbon and the like.

The present invention provides a novel electrolyte composition for a dye-sensitized solar cell. The electrolyte composition of the present invention has great efficiency of transferring solar energy into electrical energy, and has great stability, and thus the dye-sensitized solar cell having the electrolyte composition of the present invention has outstanding photoelectrical properties.

### DETAILED DESCRIPTION OF THE PREFERRED EMBODIMENTS

The detailed description of the present invention is illustrated by the following specific examples. Persons skilled in the art can conceive the other advantages and effects of the present invention based on the disclosure contained in the specification of the present invention.

Unless otherwise specified, the ingredients comprised in the electrolyte composition of the present invention, as described herein, are all based on the total weight of the electrolyte composition, and are expressed in weight percentages (wt %).

An organic amine hydroiodide (such as THI, TEAI, and etc.) and imidazolium salt (such as PMII, EMII and etc.) are mixed and added with guanidine thiocyanate, a benzimidazole derivative and solvent, so as to form a proper concentration an electrolyte composition of the present invention.

The present invention provides an electrolyte composition for a dye-sensitized solar cell, and the electrolyte composition includes 2 to 25 wt % of an organic amine hydroiodide; 2 to 25 wt % of an imidazolium salt; 0.5 to 5 wt % of iodine; 1 to 5 wt % of guanidine thiocyanate; 2 to 15 wt % of a benzimidazole derivative, a pyridine derivative or a combination thereof; and 50 to 92.5 wt % of a solvent.

The method for preparing the dye-sensitized solar cell of the present invention is a well-known, and is not specifically limited. However, the porous semiconductor film of the present invention is made of semiconductor particles. The semiconductor particle is one selected from the group consisting of silicon, titanium dioxide, tin dioxide, zinc oxide, tungsten trioxide, niobium pentoxide, strontium titanium oxide and a combination thereof. In order to form a photoanode, the semiconductor particles are prepared as a paste, so as to be applied to a transparent electrically conductive substrate by using a doctor blade, screen printing, spin coating, spraying or wet coating. In addition, the coating may be perform once or multiple times to obtain a proper thickness. The semiconductor film layer may be a single layer or multiple layers of semiconductor particles with different diameters. For example, the semiconductor particles with the diameter ranging from 5 to 50 nanometers are coated to form a thickness ranging from 5 to 20 micrometers, and then the semiconductor particles with the diameter ranging from 200 to 400 nanometers are coated to form a thickness ranging from 3 to 5 micrometers. Subsequently, the films are dried at 50 to 100° C., and sintered at 400 to 500° C. for about 30 minutes, so as to form multiple layers of semiconductor films.

The dye compound such as N-719 may be dissolved in a proper solvent to form a dye solution, and then disposed on the electrically conductive film and filled in the porous semiconductor film. The proper solvent may be, but not limited to, acetonitrile, methanol, ethanol, propanol, dimethyl foramide, N-methylpyrrolidone, and a combination thereof. Then, the transparent substrate coated with the porous semiconductor film is immersed into the dye solution, such that the dye in the dye solution is absorbed in the porous semiconductor film. After dying, the photoanode of the dye-sensitized solar cell is formed.

In the following embodiment, the method for forming the dye-sensitized solar cell is illustrated. The paste of titanium oxide particles with diameters ranging from 20 to 30 nanometers was coated by screen printing for once for multiple times on a glass substrate, which was covered by fluorinated tin oxide (FTO), and then sintered at 450° C. for 30 minutes.

The dye compound was dissolved in a mixture of acetonitrile and t-butanol, wherein the volume ratio of acetonitrile to t-butanol was 1:1, so as to form a dye solution. The above glass substrate having the porous titanium oxide film was immersed into the dye solution to absorb the dye, and then dried to form a photoanode.

Further, a glass covered with fluorinated tin oxide (FTO) was drilled to form an opening with a diameter of 0.75 millimeter for the electrolyte to be injected through. The glass covered with fluorinated tin oxide (FTO) was then coated with H₂PtCl₆ solution, heated to 400° C. and treated for about 15 minutes, so as to obtain a cathode.

A thermoplastic polymer film with a thickness being 60 micrometers was disposed between the photoanode and the cathode to form a circular region for receiving the electrolyte composition. The two electrodes were adhered via pressing at 120 to 140° C.

The electrolyte composition was injected through the opening, and then the opening was sealed with a thermoplastic polymer film. Then, the dye-sensitized solar cell of the present invention was obtained.

The advantages and effects of the present invention are illustrated in the following examples. The scope of the present invention is not limited by the examples.

### Photoelectric Efficiency Tests of Examples 1-3 and Comparative Example 1

The electrolyte compositions were prepared according to Table 1, and N-719 was used for preparing the dye-sensitized solar cell, wherein Comparative Example 1 differed from Examples in that no triethylamine hydroiodide (THI) was added in Comparative Example 1. As shown in Table 2, the photoelectric efficiency test included the short circuit current (J_{sc}), the open circuit voltage (V_{oc}), the photoelectric conversion efficiency (η) and the filling factor (FF).

TABLE 1

| | PMII | | | NBB | GuNCS | |
|---|---|---|---|---|---|---|
| No. | (M) | THI (M) | I₂ (M) | (M) | (M) | Solvent |
| Comparative | 0.65 | X | 0.05 | 0.5 | 0.1 | MPN |
| Example 1 | | | | | | |
| Example 1 | 0.65 | 0.15 | 0.05 | 0.5 | 0.1 | MPN |
| Example 2 | 0.65 | 0.15 | 0.05 | 0.5 | 0.1 | PC/EC = 1/1 |
| Example 3 | 0.65 | 0.15 | 0.05 | 0.5 | 0.1 | GBL |

TABLE 2

| No. | V_{oc} (V) | J_{sc} (mA/cm2) | FF | H (%) |
|---|---|---|---|---|
| Comparative | 0.72 | 9.84 | 61.2 | 4.35 |
| Example 1 | | | | |
| Example 1 | 0.73 | 11.43 | 60.0 | 5.00 |
| Example 2 | 0.77 | 10.60 | 61.3 | 5.02 |
| Example 3 | 0.76 | 10.68 | 58.3 | 4.71 |

In Examples 1-3, different solvent were used for preparing the electrolyte compositions, and the respective efficiency tests were performed, wherein the solvents were 3-methoxyl-propionitrile (MPN), gamma-butyrolactone (GBL), propylene carbonate (PC) and ethylene carbonate (EC), respectively. As shown in Table 2, all three dye-sensitized solar cells in Examples had higher current and voltage than that in Comparative Example 1. Similarly, the dye-sensitized solar cell having the electrolyte composition of the present invention had higher efficiency.

### Photoelectric Efficiency Tests of Examples 4-8 and Comparative Example 2

The electrolyte compositions were prepared according to Table 3, and N-719 was used for preparing the dye-sensitized solar cell, wherein Comparative Example 2 differed from Examples in that no 1-methyl-3-propylimidazolium iodide (PMII) was added in Comparative Example 2. As shown in Table 4, the photoelectric efficiency test included the short circuit current (J_{sc}), the open circuit voltage (V_{oc}), the photoelectric conversion efficiency (η) and the filling factor (FF).

TABLE 3

| | PMII | THI | I₂ | 4-TBP | NBB | GuNCS | |
|---|---|---|---|---|---|---|---|
| No. | (M) | (M) | (M) | (M) | (M) | (M) | Solvent |
| Comparative | X | 0.5 | 0.05 | 0.5 | X | X | ACN |
| Example 2 | | | | | | | |
| Example 4 | 0.45 | 0.35 | 0.05 | X | 0.5 | 0.1 | MPN |
| Example 5 | 0.55 | 0.25 | 0.05 | X | 0.5 | 0.1 | MPN |
| Example 6 | 0.65 | 0.15 | 0.05 | X | 0.5 | 0.1 | MPN |
| Example 7 | 0.65 | 0.15 | 0.05 | X | 0.5 | 0.1 | PC/EC = |
| | | | | | | | 3/7 |
| Example 8 | 0.65 | 0.15 | 0.05 | X | 0.5 | 0.1 | PC/EC = |
| | | | | | | | 4/6 |

TABLE 4

| No. | V_{oc} (V) | J_{sc} (mA/cm²) | FF | η (%) |
|---|---|---|---|---|
| Comparative | 0.74 | 8.58 | 64.7 | 4.09 |
| Example 2 | | | | |
| Example 4 | 0.74 | 8.92 | 62.3 | 4.09 |
| Example 5 | 0.75 | 9.10 | 61.1 | 4.16 |
| Example 6 | 0.76 | 9.19 | 62.4 | 4.35 |
| Example 7 | 0.766 | 9.82 | 59.15 | 4.45 |
| Example 8 | 0.76 | 10.11 | 59.29 | 4.56 |

As shown in Table 4, the dye-sensitized solar cell having the electrolyte composition including 1-methyl-3-propylimidazolium iodide (PMII) had higher current and higher efficiency. In addition, the solvent with higher boiling point was advantageous to the photoelectric conversion efficiency and voltage. Preferably, the concentration ratio of the N,N-substituted imidazolium salt to the organic amine hydroiodide was in a range from 1.1 to 5. In a preferred embodiment such as Examples 3, 7 and 8, the mixed solvents resulted in great photoelectric conversion efficiency. In one embodiment, the volume ratio of propylene carbonate to ethylene carbonate was 1:1.

### Photoelectric Efficiency Tests of Examples 1-2 and Comparative Example 3

As shown in Table 5, the electrolyte composition of Comparative Example 3 is the conventional electrolyte composition having an inorganic metal salt. As shown in Table 6, the photoelectric efficiency test included the short circuit current (J_{sc}), the open circuit voltage (V_{oc}), the photoelectric conversion efficiency (η) and the filling factor (FF).

TABLE 5

| | | | | | | | GuNCS | |
|---|---|---|---|---|---|---|---|---|
| No. | PMII (M) | LiI (M) | THI (M) | I₂ (M) | 4-TBP (M) | NBB (M) | (M) | Solvent |
| Comparative | X | 0.5 | X | 0.05 | 0.5 | X | X | MPN |
| Example 3 | | | | | | | | |
| Example 1 | 0.65 | X | 0.15 | 0.05 | X | 0.5 | 0.1 | MPN |
| Example 2 | 0.65 | X | 0.15 | 0.05 | X | 0.5 | 0.1 | PC/EC = 1/1 |

TABLE 6

| No. | V_{oc} (V) | J_{sc} (mA/cm²) | FF | η (%) |
|---|---|---|---|---|
| Comparative | 0.73 | 11.38 | 60.4 | 5.02 |
| Example 3 | | | | |
| Example 1 | 0.73 | 11.43 | 60.0 | 5.00 |
| Example 2 | 0.77 | 10.60 | 61.3 | 5.02 |

As shown in Table 6, the novel electrolyte composition of the present invention had the same property as that of the conventional electrolyte composition having an inorganic salt. The electrolyte composition of the present invention includes no inorganic salts, and thus has better compatibility among the ingredients, so as to easily form different concentrations of electrolytes, prevent the electrolyte from drying and provide stable photoelectric conversion efficiency.

In a dye-sensitized solar cell, the electrolyte involves an oxidation and a reduction, and the formulation of the electrolyte composition is critical to the efficiency and the stability of the dye-sensitized solar cell. Hence, if the electrolyte composition has the ingredient for enhancing current and voltage and has the solvent with the high boiling point, the electrolyte composition has great chemical stability. In the present invention, the electrolyte composition includes the organic amine hydroiodide (such as THI, TEAI and etc.) rather than the conventional metal salt (LiI, NaI, KI and etc.), the imidazolium salt (such as PMII, EMII and etc.), guanidine thiocyanate, one of N-methylbenzimidazole, N-butylbenzimidazole and 4-tert-butylpyridine, and the solvent with a high boiling point, so as to achieve great chemical stability. Therefore, the dye-sensitized solar cell of the present invention has high photoelectric conversion efficiency and stability.

The invention has been described using exemplary preferred embodiments. However, it is to be understood that the scope of the invention is not limited to the disclosed arrangements. The scope of the claims, therefore, should be accorded the broadest interpretation, so as to encompass all such modifications and similar arrangements.

1. An electrolyte composition for a dye-sensitized solar cell, comprising:
2 to 25 wt % of an organic amine hydroiodide;
2 to 25 wt % of an imidazolium salt;
0.5 to 5 wt % of iodine;
1 to 5 wt % of guanidine thiocyanate;
2 to 15 wt % of a benzimidazole derivative, a pyridine derivative or a combination thereof; and
50 to 92.5 wt % of a solvent.

2. The electrolyte composition of claim 1, wherein the organic amine hydroiodide is one selected from the group consisting of triethylamine hydroiodide, tripropylamine hydroiodide, tributylamine hydroiodide, tripentylamine hydroiodide, trihexylamine hydroiodide and a combination thereof.

3. The electrolyte composition of claim 1, wherein the imidazolium salt is one selected from the group consisting of 1-methyl-3-propylimidazolium iodide, 1,3-dimethylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1-methyl-3-heptylimidazolium iodide, 1-methyl-3-octylimidazolium iodide, 1,3-diethylimidazolium iodide, 1-ethyl-3-propylimidazolium iodide, 1-ethyl-3-butylimidazolium iodide, 1,3-dipropylimidazolium iodide, 1-propyl-3-butylimidazolium iodide and a combination thereof.

4. The electrolyte composition of claim 3, wherein the benzimidazole derivative, the pyridine derivative or the combination thereof is one selected from the group consisting of N-methylbenzimidazole, N-butylbenzimidazole, 4-tert-butylpyridine and a combination thereof.

5. The electrolyte composition of claim 4, wherein the solvent is one selected from the group consisting of acetonitrile, 3-methoxyl-propionitrile, N-methyl-2-pyrrolidone, gamma-butyrolactone, propylene carbonate, ethylene carbonate, and a combination thereof.

6. The electrolyte composition of claim 1, wherein the benzimidazole derivative, the pyridine derivative or the combination thereof is one selected from the group consisting of N-methylbenzimidazole, N-butylbenzimidazole, 4-tert-butylpyridine and a combination thereof.

7. The electrolyte composition of claim 1, wherein the solvent is one selected from the group consisting of acetonitrile, 3-methoxyl-propionitrile, N-methyl-2-pyrrolidone, gamma-butyrolactone, propylene carbonate, ethylene carbonate, and a combination thereof.

8. The electrolyte composition of claim 1, comprising 15.1 wt % of the organic amine hydroiodide, 2.3 wt % of the imidazolium salt, 1.3 wt % of iodine, 1.2 wt % of guanidine thiocyanate, 8.7 wt % of the benzimidazole derivative, the pyridine derivative or the combination thereof; and 71.4 wt % of the solvent.

9. A dye-sensitized solar cell, comprising:
a photoanode;
a cathode having a surface in contact with the photoanode; and
an electrolyte layer formed on the surface of the cathode and comprising:
an organic amine hydroiodide;
an imidazolium salt;
iodine;
guanidine thiocyanate;
a benzimidazole derivative, a pyridine derivative or a combination thereof; and
a solvent.

10. The dye-sensitized solar cell of claim 9, wherein the photoanode comprises a substrate, a porous semiconductor film, an electrically conductive film formed between the substrate and the porous semiconductor film, and a dye compound disposed on the electrically conductive film and filled in the porous semiconductor film.

11. The dye-sensitized solar cell of claim 10, wherein the electrolyte layer is formed between the cathode and the porous semiconductor film.

12. The dye-sensitized solar cell of claim 9, wherein the organic amine hydroiodide is one selected from the group consisting of triethylamine hydroiodide, tripropylamine hydroiodide, tributylamine hydroiodide, tripentylamine hydroiodide, trihexylamine hydroiodide and a combination thereof.

13. The dye-sensitized solar cell of claim 12, wherein the imidazolium salt is one selected from the group consisting of 1-methyl-3-propylimidazolium iodide, 1,3-dimethylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1-methyl-3-heptylimidazolium iodide, 1-methyl-3-octylimidazolium iodide, 1,3-diethylimidazolium iodide, 1-ethyl-3-propylimidazolium iodide, 1-ethyl-3-butylimidazolium iodide, 1,3-dipropylimidazolium iodide, 1-propyl-3-butylimidazolium iodide and a combination thereof; the benzimidazole derivative, the pyridine derivative or the combination thereof is one selected from the group consisting of N-methylbenzimidazole, N-butylbenzimidazole, 4-tert-butylpyridine and a combination thereof; and the solvent is one selected from the group consisting of acetonitrile, 3-methoxyl-propionitrile, N-methyl-2-pyrrolidone, gamma-butyrolactone, propylene carbonate, ethylene carbonate, and a combination thereof.

14. The dye-sensitized solar cell of claim 9, wherein the imidazolium salt is one selected from the group consisting of 1-methyl-3-propylimidazolium iodide, 1,3-dimethylimidazolium iodide, 1-methyl-3-ethylimidazolium iodide, 1-methyl-3-butylimidazolium iodide, 1-methyl-3-pentyl-imidazolium iodide, 1-methyl-3-hexylimidazolium iodide, 1-methyl-3-heptylimidazolium iodide, 1-methyl-3-octylimidazolium iodide, 1,3-diethylimidazolium iodide, 1-ethyl-3-propylimidazolium iodide, 1-ethyl-3-butylimidazolium iodide, 1,3-dipropylimidazolium iodide, 1-propyl-3-butylimidazolium iodide and a combination thereof.

15. The dye-sensitized solar cell of claim 9, wherein the benzimidazole derivative, the pyridine derivative or the combination thereof is one selected from the group consisting of N-methylbenzimidazole, N-butylbenzimidazole, 4-tert-butylpyridine and a combination thereof.

16. The dye-sensitized solar cell of claim 9, wherein the solvent is one selected from the group consisting of acetonitrile, 3-methoxyl-propionitrile, N-methyl-2-pyrrolidone, gamma-butyrolactone, propylene carbonate, ethylene carbonate, and a combination thereof.
